(19) United States
(12) Patent Application Publication
(10) Pub. No.: US 2026/0204305 A1
(43) Pub. Date: Jul. 16, 2026

(54) MEMORY DEVICE AND OPERATING METHOD THEREOF

(71) Applicant: Samsung Electronics Co., Ltd., Suwon-si (KR)

(72) Inventor: Dae Shik KIM, Suwon-si (KR)

(73) Assignee: Samsung Electronics Co., Ltd., Suwon-si (KR)

(21) Appl. No.: 19/392,399

(22) Filed: Nov. 18, 2025

(30) Foreign Application Priority Data
Jan. 10, 2025 (KR) 10-2025-0003973

(51) Int. Cl. G11C 11/16

(52) U.S. Cl. CPC G11C 11/1675; G11C 11/161; G11C 11/1673; G11C 11/1697

(57) ABSTRACT

A memory device and an operating method thereof are provided. The memory device includes an array including a first region and a second region storing a program current based on a reference resistor for distinguishing parallel and anti-parallel states of programmed memory cells, a fail bit reference indicating an allowable percentage of error bits, and a read current based on the reference resistor and the program current, and a sensing circuit con generating the read current and performing read operations, the program current including a second program current generated by adding a first offset based on the fail bit reference value to a first program current based on the reference resistor, and the read current including a first read current based on the reference resistor, and a second read current generated by adding a second offset value generated based on the first offset to the first read current.

### CROSS-REFERENCE TO RELATED APPLICATIONS

This application claims priority from Korean Patent Application No. 10-2025-0003973 filed on Jan. 10, 2025 in the Korean Intellectual Property Office, the disclosure of which is incorporated herein by reference in its entirety.

### BACKGROUND

### 1. Technical Field

The present disclosure relates to memory devices and operating methods thereof.

### 2. Description of the Related Art

In recent years, various types of electronic devices have been used. In accordance with the demand for high speed and low power consumption for the electronic devices, the demand for reliability, high speed, and low power consumption of the memory devices included in the electric devices has also increased at the same time. In order to satisfy these demands, magnetic memory elements have been proposed as memory elements of the memory devices. Since the magnetic memory elements have characteristics such as high speed operation and non-volatility, they are in the spotlight as next-generation semiconductor memory elements.

In general, the magnetic memory elements may include magnetic tunneling junction MTJ elements. The MTJ elements may include two magnetic bodies and an insulating film interposed between them. A resistance value of the MTJ elements may change depending on a magnetization direction of the two magnetic bodies. For example, when the magnetization directions of the two magnetic bodies are anti-parallel, the MTJ element may have a large resistance value, and when the magnetization directions of the two magnetic bodies are parallel, the MTJ element may have a small resistance value. Data may be programmed and read, using a difference in these resistance values.

On the other hand, in association with the reliability desired for the magnetic memory element, when a read operation on the memory device is performed by the use of an excessive magnitude of current (or voltage), a read disturbance due to switching of the spin of the magnetic memory element may become a problem, and when the read operation on the memory device is performed by the use of an insufficient magnitude of current (or voltage), a read fail may occur. In particular, since the value of the read current (or voltage) may be stored in the memory device by a memory vendor in a test step, the value of the read current (or voltage) determined once has a significant effect on the performance of the memory device.

### SUMMARY

Aspects of the present inventions provide memory devices having improved durability and/or reliability.

Aspects of the present inventions also provide operating methods of a memory device having improved durability and/or reliability.

However, aspects of the present inventions are not restricted to the one set forth herein. The above and other aspects of the present inventions will become more apparent to one of ordinary skill in the art to which the present inventions pertain by referencing the detailed description of the present inventions given below.

Specific matters of other example embodiments are included in the detailed description and drawings.

According to some aspects of the present disclosure, there is provided a memory device including a memory cell array including a first region and a second region configured to store a value of a program current discriminated, based on a value of a reference resistor for distinguishing between a parallel state and an anti-parallel state of a programmed memory cell, a fail bit reference value indicating a percentage of error bits allowable in the memory cell array, and a value of a read current discriminated based on the value of the reference resistor and the value of the program current, and a sensing circuit configured to generate the read current and perform a read operation on the first region based on the read current, the value of the program current including a value of a second program current generated by adding a first offset value discriminated based on the fail bit reference value to a value of a first program current discriminated based on the value of the reference resistor, and the value of the read current including a value of a first read current discriminated based on the value of the reference resistor, and a value of a second read current generated by adding a second offset value generated based on the first offset to the value of the first read current.

According to some aspects of the present disclosure, there is provided an operating method of a memory device, including programming a memory device to a first state, counting fail bits of the memory device programmed to the first state for each reference resistor, using a plurality of resistors having different values from each other, programming the memory device to a second state, counting fail bits of the memory device programmed to the second state for each reference resistor, using the plurality of resistors, selecting a reference resistor among the plurality of resistors, based on the counting results associated with the first state and the counting results associated with the second state, discriminating a value of a first program current for the memory device based on the value of the selected reference resistor, discriminating a value of a second program current for the memory device, based on the value of the first program current and a fail bit reference value indicating a percentage of error bits allowable in the memory device, discriminating a value of a first read current for the memory device based on the value of the selected reference resistor, and discriminating a value of a second read current for the memory device, based on the value of the first read current and a first offset value obtained by subtracting the value of the first program current from the value of the second program current.

According to some aspects of the present disclosure, there is provided a memory device including a memory cell array including a first region, and a second region that stores a value of a program current discriminated, based on a value of a reference resistor for distinguishing between a parallel state and an anti-parallel state of a programmed memory cell and a fail bit reference value indicating a percentage of error bits allowable in the memory cell array, and a value of a read current discriminated based on the value of the reference resistor and the value of the program current, and a sensing circuit configured to generate the read current and perform a read operation on the first region based on the read current, the value of the program current including a value of a second program current generated by adding a first offset value discriminated based on the fail bit reference value to a value of a first program current discriminated based on the value of the reference resistor, and the value of the read current includes a value of a first read current discriminated based on the value of the reference resistor, and a value of a second read current generated by adding a second offset value generated based on the first offset to the value of the first read current, a percentage of error bits generated based on the value of the second program current does not exceed the fail bit reference value, and a ratio of the first offset value to the value of the first program current is equal to a ratio of the second offset value to the value of the first read current.

According to some aspects of the present disclosure, there is provided a test system including a memory device including a memory cell array including a first region and a second region configured to store a value of a reference resistor, a value of a program current, and a value of a read current, and a sensing circuit configured to generate the read current and perform a read operation on the first region based on the read current; and a test device configured to store a fail bit reference value indicating a percentage of error bits allowable in the memory device, determine the value of the program current based on the value of the reference resistor and dummy data for distinguishing between a parallel state and an anti-parallel state of a programmed memory cell of the memory device, and determine the value of the read current discriminated based on the value of the reference resistor, the value of the program current, and dummy data.

According to some aspects of the present disclosure of the test system, the second region includes an anti-fuse cell array.

### BRIEF DESCRIPTION OF THE FIGURES

The above and other objects and features of the present disclosure will become apparent by describing in detail example embodiments thereof with reference to the accompanying drawings.

FIG. 1 is a diagram showing a substrate on which memory devices according to some example embodiments are integrated.

FIG. 2 is a diagram for illustrating some example embodiments of the memory device of FIG. 1.

FIG. 3 is a circuit diagram showing some example embodiments of the memory cell array of FIG. 2.

FIG. 4 is a circuit diagram showing some example embodiments of the memory cell array of FIG. 2.

FIGS. 5 and 6 are diagrams showing some example embodiments of the memory cell of FIG. 3.

FIG. 7 is a conceptual diagram for illustrating some example embodiments associated with the memory cell of FIG. 4.

FIG. 8 is a diagram for illustrating discrimination of a value of optimal reference resistor for the memory device according to some example embodiments of the present inventions.

FIG. 9 is a diagram for illustrating a program state of the memory cell of FIG. 5 or 6.

FIG. 10 is a diagram for illustrating a relationship between the optimal reference resistor value determined on the basis of the size and perpendicular magnetic anisotropy of the memory cell at the time of the test operation on the memory device and the value of the optimal program current corresponding thereto.

FIGS. 11 to 13 are diagrams for illustrating a method of determining the value of the optimal program current on the basis of a fail bit reference value at the time of the test operation on the memory device.

FIG. 14 is a diagram for illustrating a relationship between the optimal reference resistor value determined on the basis of the size of the memory cell at the time of the test operation on the memory device and the value of optimal read current corresponding thereto.

FIG. 15 is a table for illustrating the value of optimal program current and the value of optimal read current on the basis of the test operation on the memory device.

FIGS. 16 and 17 are flowcharts for illustrating a method for testing a memory device according to some example embodiments of the present disclosure.

FIGS. 18 to 20 are diagrams for illustrating a test operation on the memory device according to some example embodiments.

FIG. 21 is a diagram showing some example embodiments of the driver of FIG. 18.

FIGS. 22 and 23 are diagrams for illustrating some example embodiments of a driver that operates on the basis of the code value which is output from the voltage generator of FIG. 21.

FIG. 24 is a diagram for illustrating a test system according to some example embodiments of the present disclosure.

### DETAILED DESCRIPTION

Hereinafter, example embodiments of the present inventions will be described in detail with reference to the attached drawings. The same reference numerals are used for the same components in the drawings, and the repeated description will not be provided.

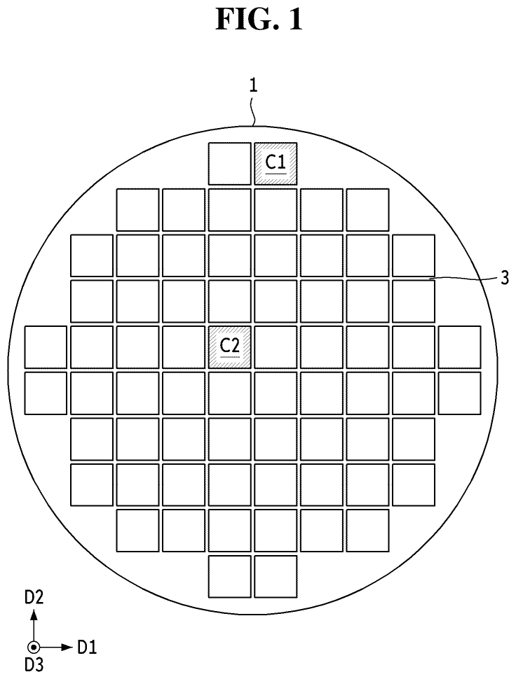

FIG. 1 is a diagram showing a substrate on which memory devices according to some example embodiments are integrated.

Referring to FIG. 1, a substrate 1 may include a plurality of memory devices including a first memory device C1 and a second memory device C2, and a scribe line region 3 between the memory devices. The memory devices may be arranged two-dimensionally along a first direction D1 and a second direction D2. Each memory device may be surrounded by the scribe line region 3. That is, the scribe line region 3 may be disposed between the memory devices adjacent to each other in the first direction D1, and between the memory devices adjacent to each other in the second direction D2.

In some example embodiments, the substrate 1 may be a semiconductor substrate such as a semiconductor wafer. The substrate 1 may be a bulk silicon substrate, a silicon-on-insulator (SOI) substrate, a germanium substrate, a germanium-on-insulator (GOI) substrate, a silicon-germanium substrate or a substrate of an epitaxial thin form acquired by performing a selective epitaxial growth (SEG). For example, the substrate 1 may include at least one of silicon (Si), germanium (Ge), silicon germanium (SiGe), gallium arsenide (GaAs), indium gallium arsenide (InGaAs), aluminum gallium arsenide (AlGaAs) or a mixture thereof. The substrate 1 may have a crystal structure of a single crystal.

In some example embodiments, the first memory device C1 may represent a memory device formed relatively towards an outer side the substrate 1, and the second memory device C2 may represent a memory device formed relatively towards an inner side the substrate 1.

Meanwhile, depending on the position at which the memory device is formed in the substrate 1, the program characteristics and the reference resistor characteristics of the memory device may differ. For example, if the memory devices formed on the substrate 1 includes MRAM cells, the size of the MRAM cell may vary depending on the position of the memory device in the substrate 1.

For example, the size of the MRAM cell of the first memory device C1 located relatively outside the substrate 1 may be relatively small due to reasons for manufacturing process. On the other hand, the size of the MRAM cell of the second memory device C2 located relatively inside the substrate 1 may be relatively large due to reasons for manufacturing process. According to some example embodiments of the present inventions, the relative position of the memory device in the substrate 1 is taken into consideration to determine the optimal program voltage level for that chip. Thus, the reliability and/or durability of the memory device may be improved. This will be described below in detail. Herein, “optimal” may be used to describe a value that meets or exceeds performance requirements, such as a program voltage level that may reliability program a memory device without impacting durability.

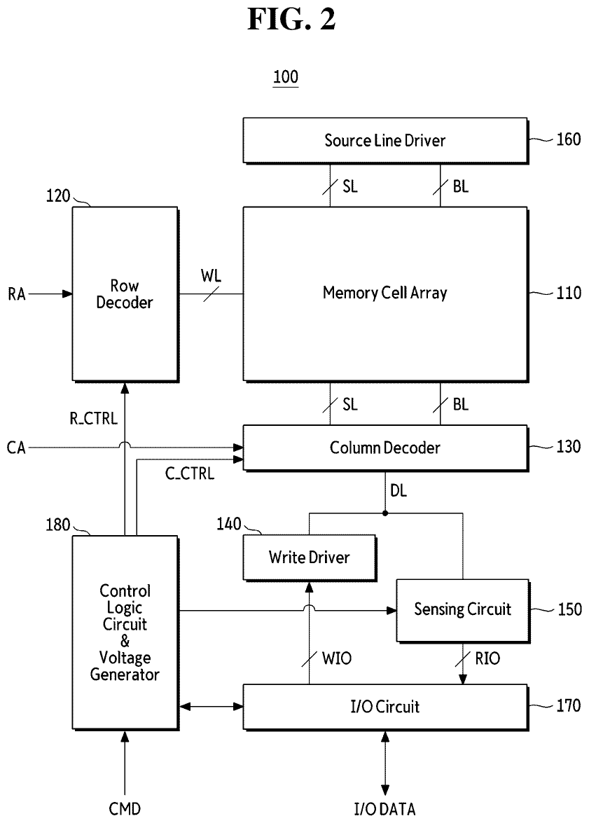

FIG. 2 is a diagram for illustrating some example embodiments of the memory device of FIG. 1. Referring to FIG. 2, the memory device 100 may be the first memory device C1 or the second memory device C2 of FIG. 1. The memory device 100 may include a memory cell array 110, a row decoder 120, a column decoder 130, a write driver 140, a sensing circuit 150, a source line driver 160, an input/output circuit 170, and a control logic circuit and voltage generator 180.

The memory cell array 110 may include a plurality of memory cells each configured to store data. For example, each memory cell may include a variable resistance element in which stored data value is discriminated depending on a resistance value. For example, each memory cell may include a magneto-resistive RAM (MRAM), a spin transfer torque MRAM (STT-MRAM), a phase change RAM (PRAM), a resistive RAM (ReRAM), and the like. However, in the following description, each memory cell of the memory is assumed to include an MRAM.

The memory cells that constitute the memory cell array 110 may be connected to source lines SL, bit lines BL, and word lines WL. For example, the memory cells arranged along a row may be commonly connected to each word line, and the memory cells arranged along a column may be commonly connected to each source line and each bit line.

The row decoder 120 may select (or drive) a word line WL connected to a memory cell for which a read operation or a program operation is performed on the basis of a row address RA and a row control signal R_CTRL. The row decoder 120 may provide a driving voltage, which is input from the control logic circuit and the voltage generator 180, to the selected word line.

The column decoder 130 may select a bit line BL and/or a source line SL connected to a memory cell on which a read operation or a program operation is performed on the basis of a column address CA and a column control signal C_CTRL.

The write driver 140 may drive a program voltage (or write current) for storing write data in the memory cell selected by the row decoder 120 and the column decoder 130 at the time of the program operation. For example, at the time of the program operation on the memory device 100, the write driver 140 may store write data in the selected memory cell, by controlling the voltage of the data line DL on the basis of write data that is input from the input/output circuit 170 through the write input/output line WIO.

Meanwhile, for convenience of explanation and simplicity of the drawings, the data line DL is shown, but it may be understood that the data line DL corresponds to the bit line BL and source line SL selected by the column decoder 130.

The sensing circuit 150 may sense a signal which is output through the data line DL at the time of the read operation, and discriminate the value of data stored in the memory cell. The sensing circuit 150 may be connected to the column decoder 130 through the data line DL, and may be connected to the input/output circuit 170 through the read input/output line RIO. The sensing circuit 150 may output the sensed read data to the input/output circuit 170 through the read input/output line RIO.

The source line driver 160 may drive the source line SL to a specific voltage level under the control of the control logic circuit and the voltage generator 180. For example, the source line driver 160 may be provided with a voltage for driving the source line SL from the control logic circuit and the voltage generator 180. For example, when a program operation is to be performed so that the memory cell has a high resistance value (e.g., anti-parallel state) or when a program operation is to be performed so that the memory cell has a low resistance value (e.g., parallel state), the values of the voltages applied from the source line driver 160 to the source line SL may differ from each other.

Meanwhile, although not shown in the drawings, the memory device 100 may further include an anti-fuse array. The anti-fuse array may include anti-fuses disposed along rows and columns. For example, the anti-fuses may be one-time programmable (OTP) memories and may be non-volatile. The anti-fuse array may be programmed with information about the memory device 100. For example, the anti-fuse array may be programmed with information about a fail address of the memory cell array 110, information about internal currents (e.g., program currents, read currents) of the memory device 100, and the like. In particular, the anti-fuse array may be programmed with information about values of the optimal program current and values of optimal read current discriminated in a test step of the memory device according to some example embodiments of the present disclosure.

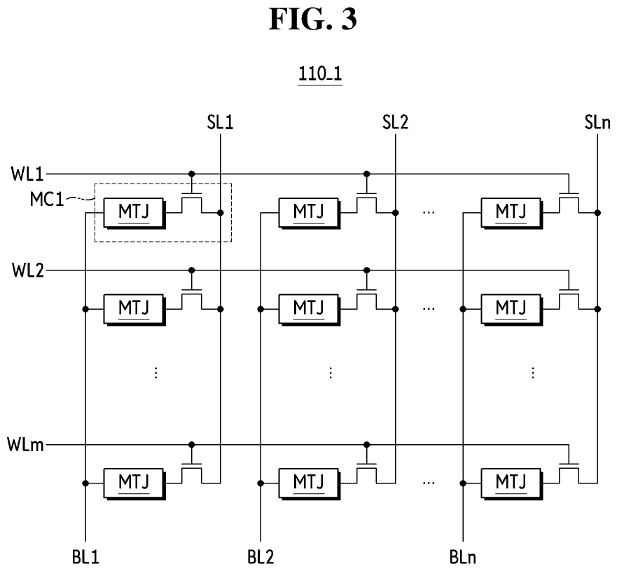

FIG. 3 is a circuit diagram showing some example embodiments of the memory cell array of FIG. 2. Referring to FIG. 3, a memory cell array 110_1 may include a plurality of memory cells disposed along rows and columns. Each memory cell may include a magnetic tunneling junction element MTJ and a cell transistor CT. Since the MTJ element constituting each memory cell is programmed to have a specific resistance value, data corresponding to the specific resistance value may be stored in each memory cell. As an example, in FIG. 3, among the plurality of memory cells, a memory cell indicated by a dotted box is indicated as a first memory cell MC1.

The plurality of memory cells may be connected to word lines WL1 to WLm, bit lines BL1 to BLn, and source lines SL1 to SLn. One end of the MTJ element may be connected to the first bit line BL1, and the other end of the MTJ element may be connected to one end of the cell transistor CT. The other end of the cell transistor CT may be connected to the source line SL1, and the gate electrode of the cell transistor CT may be connected to the first word line WL1.

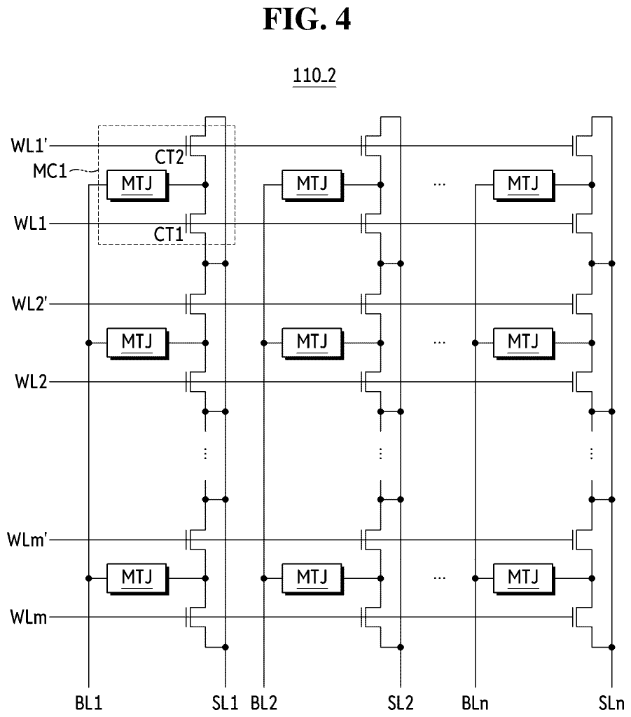

FIG. 4 is a circuit diagram showing some example embodiments of the memory cell array of FIG. 2. Referring to FIG. 4, a memory cell array 110_2 may include a plurality of memory cells disposed along row and column directions. Each memory cell may include a magnetic tunneling junction element MTJ and two cell transistors. For example, in FIG. 4, a first memory cell MC1 indicated by a dotted box among the plurality of memory cells is shown as including the MTJ element, the first cell transistor CT1, and the second cell transistor CT2.

The first memory cell MC1 may have a structure in which the first cell transistor CT1 and the second cell transistor CT2 share one MTJ element. One end of the MTJ element may be connected to the first bit line BL1, and the other end may be connected to one end of the first cell transistor CT1 and one end of the second cell transistor CT2. The other end of the first cell transistor CT1 and the other end of the second cell transistor CT2 may be connected to the first source line SL1. The gate electrode of the first cell transistor CT1 may be connected to the first word line WL1, and the gate electrode of the second cell transistor CT2 may be connected to the first sub-word line WL1'. Each of the first cell transistor CT1 and the second cell transistor CT2 may be switched on or off by a signal (or voltage) provided through a word line or a sub-word line.

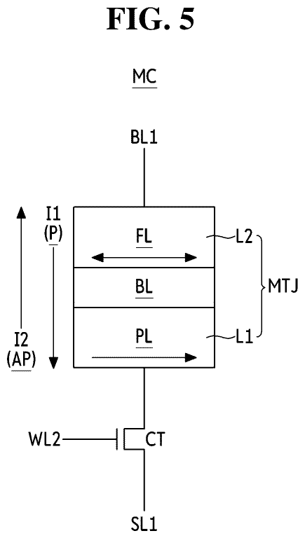

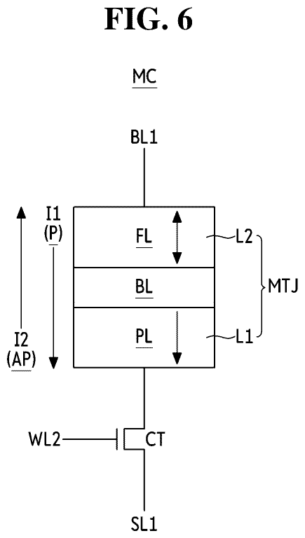

FIGS. 5 and 6 are diagrams showing some example embodiments of the memory cell of FIG. 3. Referring to FIGS. 5 and 6, the MTJ element may include a first magnetic layer L1, a second magnetic layer L2, and a barrier layer BL (or tunneling layer) between them. The barrier layer BL may include at least one of a magnesium (Mg) oxide film, a titanium (Ti) oxide film, an aluminum (Al) oxide film, a magnesium-zinc (Mg—Zn) oxide film or a magnesium-boron (Mg—B) oxide film, or a combination thereof. Each of the first magnetic layer L1 and the second magnetic layer L2 may include at least one magnetic layer.

Specifically, the first magnetic layer L1 may include a reference layer (e.g., a pinned layer PL) having a magnetization direction pinned in a specific direction, and the second magnetic layer L2 may include a free layer FL having a magnetization direction that is changeable to be parallel or anti-parallel to the magnetization direction of the reference layer. However, although FIGS. 5 and 6, according to some example embodiments, disclose a case where the first magnetic layer L1 includes the reference layer PL and the second magnetic layer L2 includes the free layer FL, example embodiments of the present inventions are not limited thereto. For example, unlike those shown in FIGS. 5 and 6, it goes without saying that the first magnetic layer L1 may include the free layer and the second magnetic layer L2 may include the pinned layer.

In some example embodiments, as shown in FIG. 5, the magnetization directions may be parallel or substantially parallel to an interface between the barrier layer BL and the first magnetic layer L1. In this case, each of the reference layer and the free layer may include a ferromagnetic material. For example, the reference layer may further include an anti-ferromagnetic material for pinning the magnetization direction of the ferromagnetic material.

In some example embodiments, as shown in FIG. 6, the magnetization directions may be perpendicular or substantially perpendicular to the interface between the barrier layer BL and the first magnetic layer L1. In this case, each of the reference layer and the free layer may include at least one or a combination of a perpendicular magnetic material (e.g., CoFeTb, CoFeGd, and CoFeDy), a perpendicular magnetic material having an L10 structure, CoPt of a hexagonal close packed lattice structure, and a perpendicular magnetic structure. The perpendicular magnetic material having an L10 structure may include at least one or a combination of FePt of the L10 structure, FePd of the L10 structure, CoPd of the L10 structure, CoPt of the L10 structure, and the like. The perpendicular magnetic structure may include magnetic layers and non-magnetic layers that are stacked alternately and repeatedly. For example, the perpendicular magnetic structure may be (Co/Pt)n, (CoFe/Pt)n, (CoFe/Pd)n, (Co/Pd)n, (Co/Ni)n, (CoNi/Pt)n, (CoCr/Pt)n or (CoCr/Pd)n (n is the number of layers). Here, the reference layer may be thicker than the free layer, or a coercivity of the reference layer may be greater than coercivity of the reference layer.

In some example embodiments, a write current I1 may flow when a relatively high level of voltage is applied to the bit line BL1 and a relatively low level of voltage is applied to the source line SL1. In this case, the magnetization direction of the second magnetic layer L2 may become equal to the magnetization direction of the first magnetic layer L1, and the MTJ element may have a low resistance value (e.g., parallel state).

On the other hand, when a relatively high level of voltage is applied to the source line SL1 and a relatively low level of voltage is applied to the bit line BL1, a current I2 may flow. In this case, the magnetization direction of the second magnetic layer L2 may be opposite to that of the first magnetic layer L1, and the MTJ element may have a high resistance value (e.g., anti-parallel state).

In some example embodiments, when the MTJ element is in the parallel state, the memory cell MC may be considered to store data of a first value (e.g., logic “0”). On the other hand, when the MTJ element is in the anti-parallel state, the memory cell MC may be considered to store data of a second value (e.g., logic “1”).

On the other hand, although only one cell transistor CT is shown in FIGS. 5 and 6, the configurations shown in FIGS. 5 and 6 are also applicable to the memory cell of FIG. 4. In this case, the cell transistors CT1 and CT2 may be connected to one end of the MTJ element. A current path only changes depending on which of the cell transistors CT1 and CT2 is turned on, and the basic principle, operation and the like of the MTJ element may be applied as it is.

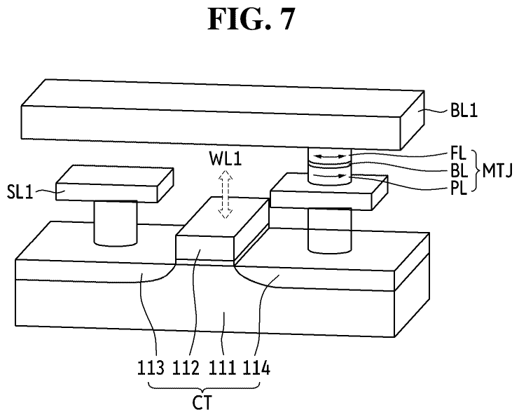

FIG. 7 is a conceptual diagram for illustrating some example embodiments associated with the memory cell of FIG. 4.

Referring to FIG. 7, the cell transistor CT may include a body substrate 111, a gate electrode 112, and junctions 113 and 114. The junction 113 may be formed on the body substrate 111, and be connected to the source line SL1. The junction 114 may be formed on the body substrate 111, and be connected to the bit line BL1 through the MTJ element. The gate electrode 112 may be formed on the body substrate 111 between the junctions 113 and 114, and be connected to the word line WL1. Meanwhile, the configuration of FIG. 7 shows some example embodiments, and when two cell transistors share one MTJ element as in some example embodiments described through FIG. 6, a configuration modified from the configuration shown in FIG. 7 may be further adopted.

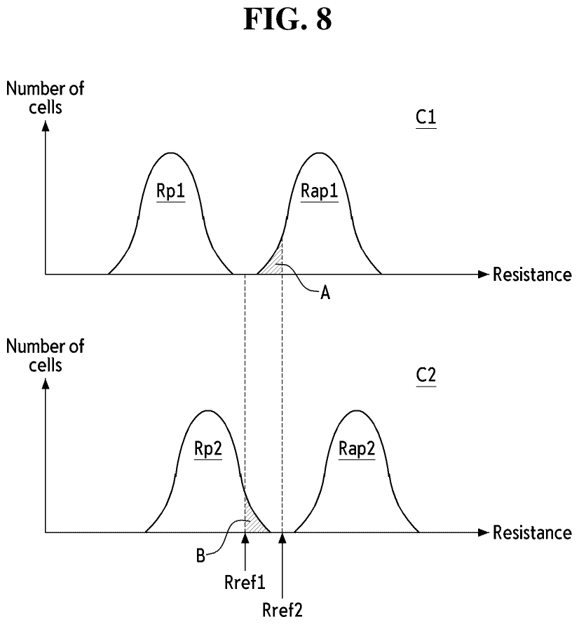

FIG. 8 is a diagram for illustrating discrimination of a value of optimal reference resistor for the memory device according to some example embodiments of the present inventions.

Referring to FIG. 8, as briefly described above through FIG. 1, the program characteristics of the memory device may vary depending on the location at which the memory device is formed inside the substrate 1. For example, a resistance distribution corresponding to the first memory device C1 may be different from the resistance distribution corresponding to the second memory device C2. In other words, the resistance value of the first memory device C1 may be generally smaller than the resistance value of the second memory device C2. This is because the size of the MTJ element constituting the first memory device C1 is generally greater than the size of the MTJ element constituting the second memory device C2.

First, referring to a graph corresponding to the first memory device C1, a resistance distribution Rp1 of the memory cells programmed in the parallel state and the resistance distribution Rap1 of the memory cells programmed in the anti-parallel state may be distinguished by a first reference resistor Rref1. That is, a first reference resistor Rref1 is a criterion for discriminating the data value stored in the MRAM cell, and a memory cell having a resistance value lower than the first reference resistor Rref1 may be considered to store first value, and a memory cell having a resistance value higher than the first reference resistor Rref1 may be considered to store a second value.

Referring to a graph corresponding to the second memory device C2, the resistance distribution Rp2 of the memory cells programmed in the parallel state and the resistance distribution Rap2 of the memory cells programmed in the anti-parallel state may be distinguished by a second reference resistor Rref2. That is, the second reference resistor Rref2 is a criterion for discriminating the data value stored in the MRAM cell, a memory cell having a resistance value lower than the second reference resistor Rref2 may be considered to store the first value, and a memory cell having a resistance value higher than the second reference resistor Rref2 may be considered to store the second value.

However, if the same program and read conditions are applied to the memory devices C1 and C2 provided from one substrate 1, an error may occur at the time of the program and read operations.

For example, assuming a program operation is performed by applying the second reference resistor Rref2 to the first memory device C1, the memory cells programmed to have a resistance value inside a region A may be considered to have a parallel state Rp1, contrary to the original intention.

The magnitude of the read current corresponding to the first reference resistor Rref1 may be somewhat large to determine the program state of the second memory device C2. This is because a relatively small read current is desirable to discriminate the program state of the second memory device C2, which has a relatively small size of MTJ element. That is, when the read operation is performed on the second memory device C2 using the read current corresponding to the first reference resistor Rref1, a read disturbance may occur due to a change in spin state of the memory cell.

In contrast, if the program operation is performed by applying the first reference resistor Rref1 to the second memory device C2, the memory cells programmed to have a resistance value inside the region B may be considered to have an anti-parallel state Rap2, contrary to the original intention.

The magnitude of the optimal read current corresponding to the second reference resistor Rref2 may be somewhat small to discriminate the program state of the first memory device C1. This is because a relatively large read current is desirable to discriminate the program state of the first memory device C1, which has a relatively large size of MTJ element. That is, when the read operation is performed on the first memory device C1 using the read current corresponding to the second reference resistor Rref2, a read fail may occur.

That is, when a uniform reference resistor value is applied to the memory device, unintended program errors and read errors may occur. Therefore, it may be beneficial for determining an optimal reference resistor value to determine a value of an optimal program current and a value of an optimal read current to be provided to each memory device.

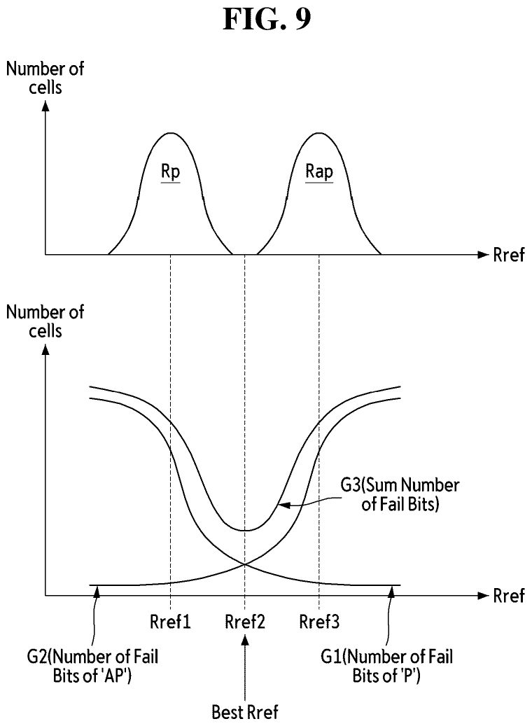

FIG. 9 is a diagram for illustrated a program state of the memory cell of FIG. 5 or 6.

Referring to FIG. 9, a pre-program operation on the memory device may be performed at the time of a test operation on the memory device. The pre-program operation here is not for storing data, but may refer to a program operation for finding an optimal reference resistor for distinguishing between a parallel state and an anti-parallel state in a test step of the memory device. For example, the program current (or program voltage) applied to the memory device at the time of a pre-program operation may be higher than the level of program current used at the time of a typical program operation after product shipment. This may be related to prevention of program fails to perform an accurate test.

First, the memory cells of the memory device may be programed to a parallel state, using a test device (e.g., automatic test equipment (ATE)). The distribution of the resistance values of the memory cells programmed to the parallel state may be equal to Rp. After that, the number of fail bits for the memory device may be counted, by the use of the test device. For example, when the fail bits are counted using a relatively low value of reference resistor (e.g., the first reference resistor Rref1), because memory cells having a resistance value larger than the first reference resistor Rref1 are processed as program fail, the number of fail bits may be very large. And the larger the value of the reference resistor becomes, the smaller the number of fail bits for the memory device may become. The trend of the number of counted fail bits is shown in a graph indicated by G1.

Further, the memory cells of the memory device may be programmed to the anti-parallel state, using the test device. The distribution of the resistance values of the memory cells programmed to the anti-parallel state may be equal to Rap. After that, the number of fail bits for the memory device may be counted, using the test device. For example, when the fail bits are counted, using a relatively low value of reference resistor (e.g., the first reference resistor Rref1), the number of fail bits may be very small. However, as the value of the reference resistor increases (e.g., some point between the second reference resistor Rref2 and the third reference resistor Rref3), the number of fail bits for the memory device may increase. The trend of the number of the counted fail bits is shown in a graph indicated by G2.

Next, the test device may discriminate an optimal reference resistor value, using the number of counted fail bits. For example, the test device may sum the graph G1 indicating the number of fail bits measured in the parallel state and the graph G2 indicating the number of fail bits measured in the anti-parallel state. As the summation result, the graph indicated by G3 may be derived. The resistance value (e.g., Rref2) corresponding to the smallest number of fail bits in the graph indicated by G3 may be the optimal reference resistor value of the memory device.

The test device may then determine a value of optimal program current (or program voltage) for the memory device on the basis of the optimal reference resistor value (e.g., Rref2). The value of the program current (or program voltage) may be derived from the size of the MRAM cell measured in advance, the value of the reference resistor according to the size of the MRAM cell, and the trend of the value of the program current according to the value of the reference resistor.

In some example embodiments, when the optimal reference resistor value is relatively small (e.g., Rref1), this case may mean that the size of the MTJ element constituting the memory device is relatively large, which may mean that a relatively high value of the program current is beneficial. In contrast, when the optimal reference resistor value is relatively large (e.g., Rref3), this case may mean that the size of the MRAM cells constituting the memory device is relatively small, which may mean that a relatively low value of the program current is beneficial.

When applying this to the first memory device C1 and the second memory device C2 of FIG. 1, the optimal reference resistor value of the first memory device C1 of FIG. 1 is relatively large (e.g., Rref3), and from which, it may be derived that a relatively small program current is beneficial at the time of the program operation on the first memory device C1. Similarly, the optimal reference resistor value of the second memory device C2 is relatively small (e.g., Rref1), and from which, it may be derived that a relatively large program current is beneficial at the time of the program operation on the second memory device C2.

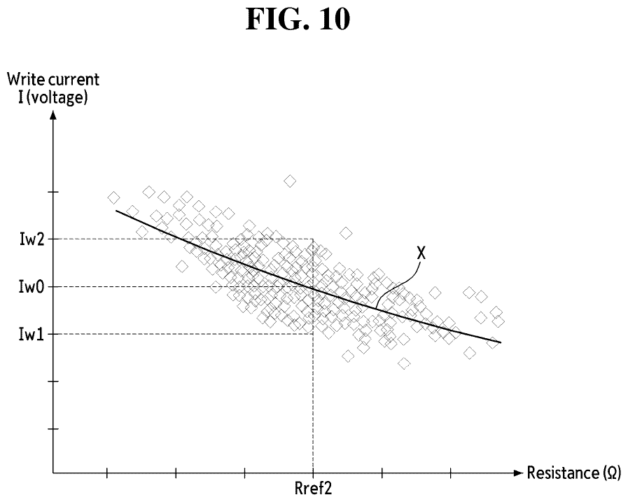

FIG. 10 is a diagram for illustrating a relationship between the optimal reference resistor value determined on the basis of the size and perpendicular magnetic anisotropy of the memory cell at the time of the test operation on the memory device and the value of the optimal program current corresponding thereto.

Referring to FIG. 10, in some example embodiments, the value of the reference resistor of the memory device and the value optimal program current (or program voltage) corresponding thereto may be inversely proportional or substantially inversely proportional to each other. However, the value of the reference resistor of the memory device and the value of the optimal program current corresponding thereto may not be exactly inversely proportional to each other.

Furthermore, in some example embodiments, the value of the optimal program current for the plurality of MRAM cells having value of the same reference resistor in the memory device may be different values from each other. For example, when the sizes of the plurality of MRAM cells are equal to each other, the optimal reference resistor values may be equal to each other. Considering only the optimal reference resistor value according to the size of the cell, the value of the reference resistor of the MRAM cells included in the memory device and the value of the optimal program current corresponding thereto may correspond to each other along an X-ray. For example, the value of the optimal program current for the plurality of MRAM cells having the second reference resistor value Rref2 may be a first program current Iw0. This process is called coarse trim of the program current.

However, in actual test, the value of the optimal program current for the plurality of MRAM cells having the same cell size may be distributed within the range of the second program current Iw1 to the third program current Iw2. This is because the value of program current may be affected not only by the size of the MRAM cell but also by the perpendicular magnetic anisotropy (PMA) of each cell. Therefore, the first program current Iw0 based on the value of the reference resistor may be beneficial to trim more finely. Detailed description of the fine trim method will be given below.

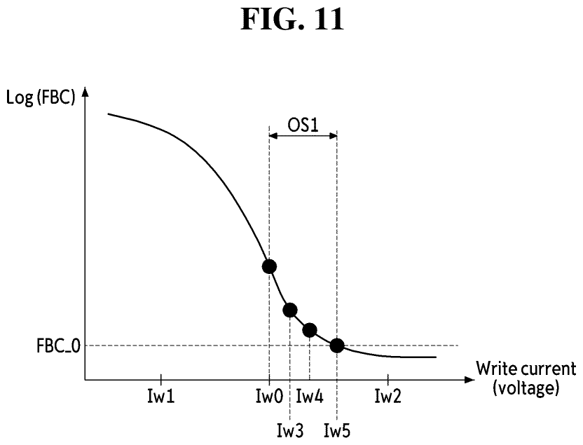

FIGS. 11 to 13 are diagrams for illustrating a method of determining the value of the optimal program current on the basis of a fail bit reference value at the time of the test operation on the memory device.

Referring to FIGS. 10 and 11, it is possible to test whether a fail bit count value Log(FBC) does not exceed a fail bit reference value FBC_0 when a first program current Iw0 is applied to an MRAM cell having a second reference resistor value Rref2 as an optimal reference resistor value. The fail bit reference value FBC_0 may be a value representing a percentage of error bits that is allowable in the memory device.

At the time of the test operation on a plurality of MRAM cells which are included in the memory device and have the second reference resistor value Rref2 as an optimal reference resistor value, the plurality of MRAM cells are programmed with a first program current Iw0, and the test is performed whether the fail bit count value Log(FBC) obtained by the program operation does not exceed the fail bit reference value FBC_0.

If the fail bit count value Log(FBC) according to the program operation based on the first program current Iw0 exceeds the fail bit reference value FBC_0, the plurality of MRAM cells may be programmed with a fourth program current Iw3 that is greater than the first program current Iw0. For example, if the value of the program current is configured with 4 bits, when the value of the first program current Iw0 is logic “0001”, the value of the fourth program current Iw3 may be logic “0010”. Then, the test is performed whether the fail bit count value Log(FBC) according to the program operation based on the fourth program current Iw3 does not exceed the fail bit reference value FBC_0.

If the fail bit count value Log(FBC) according to the program operation based on the fourth program current Iw3 exceeds the fail bit reference value FBC_0, the plurality of MRAM cells may be programmed by a fifth program current Iw4 that is greater than the fourth program current Iw3. For example, if the value of the program current is configured with 4 bits, when the value of the fourth program current Iw3 is logic “0010”, the value of the fifth program current Iw4 may be logic “0011”. Further, the test is performed whether the fail bit count value Log(FBC) according to the program operation based on the fifth program current Iw4 exceeds the fail bit reference value FBC_0.

If the fail bit count value Log(FBC) according to the program operation based on the fifth program current Iw4 exceeds the fail bit reference value FBC_0, the plurality of MRAM cells may be programmed by a sixth program current Iw5 that is greater than the fifth program current Iw4. For example, if the value of the program current is configured with 4 bits, when the value of the fifth program current Iw4 is logic “0011”, the value of the sixth program current Iw5 may be logic “0100”. Further, the test is performed whether the fail bit count value Log(FBC) according to the program operation based on the sixth program current Iw5 does not exceed the fail bit reference value FBC_0.

If the fail bit count value Log(FBC) according to the program operation based on the sixth program current Iw5 does not exceed the fail bit reference value FBC_0, the sixth program current Iw5 may be an optimal program current for the plurality of MRAM cells.

For example, for an MRAM cell having the second reference resistor value Rref2 as the optimal reference resistor value, the value of the sixth program current Iw5, which is an optimal program current finely trimmed by the fail bit reference value FBC_0, may be a value obtained by adding a first offset value OS1 to the value of the first program current Iw0, which is an optimal program current coarsely trimmed by the second reference resistor value Rref2.

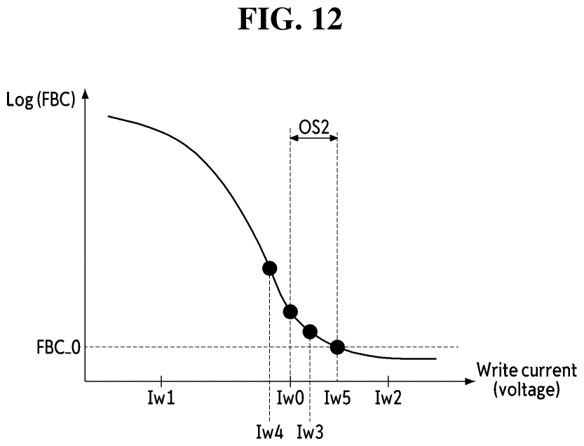

Referring to FIGS. 10 and 12, it is possible to test whether the fail bit count value Log(FBC) does not exceed the fail bit reference value FBC_0 when the first program current Iw0 is applied to the MRAM cell having the second reference resistor value Rref2 as the optimal reference resistor value.

At the time of the test operation on a plurality of MRAM cells which are included in the memory device and have the second reference resistor value Rref2 as the optimal reference resistor value, the plurality of MRAM cells are programmed with the first program current Iw0, and the test is performed whether the fail bit count value Log(FBC) due to the program operation does not exceed the fail bit reference value FBC_0.

If the fail bit count value Log(FBC) according to the program operation based on the first program current Iw0 exceeds the fail bit reference value FBC_0, the plurality of MRAM cells may be programmed with a fourth program current Iw3 that is greater than the first program current Iw0. For example, if the value of the program current is configured with 4 bits, when the value of the first program current Iw0 is logic “0001”, the value of the fourth program current Iw3 may be logic “0010”. Further, the test is performed whether the fail bit count value Log(FBC) according to the program operation based on the fourth program current Iw3 does not exceed the fail bit reference value FBC_0.

If the fail bit count value Log(FBC) according to the program operation based on the fourth program current Iw3 exceeds the fail bit reference value FBC_0, the plurality of MRAM cells may be programmed with a fifth program current Iw4 that is smaller than the first program current Iw0. For example, if the value of the program current is configured with 4 bits, when the value of the first program current Iw0 is logic “0001”, the value of the fifth program current Iw4 may be logic “0000”. Further, the test is performed whether the fail bit count value Log(FBC) according to the program operation based on the fifth program current Iw4 does not exceed the fail bit reference value FBC_0.

If the fail bit count value Log(FBC) according to the program operation based on the fifth program current Iw4 exceeds the fail bit reference value FBC_0, the plurality of MRAM cells may be programmed with a sixth program current Iw5 that is greater than the fourth program current Iw3. For example, if the value of the program current is configured with 4 bits, when the value of the fourth program current Iw3 is logic “0010”, the value of the sixth program current Iw5 may be logic “0011”. Further, the test is performed whether the fail bit count value Log(FBC) according to the program operation based on the sixth program current Iw5 exceeds the fail bit reference value FBC_0.

If the fail bit count value Log(FBC) according to the program operation based on the sixth program current Iw5 does not exceed the fail bit reference value FBC_0, the sixth program current Iw5 may be an optimal program current for the plurality of MRAM cells.

For example, for an MRAM cell having the second reference resistor value Rref2 as the optimal reference resistor value, the value of the sixth program current Iw5, which is an optimal program current finely trimmed by the fail bit reference value FBC_0, may be a value obtained by adding a second offset value OS2 to the value of the first program current Iw0, which is an optimal program current coarsely trimmed by the second reference resistor value Rref2.

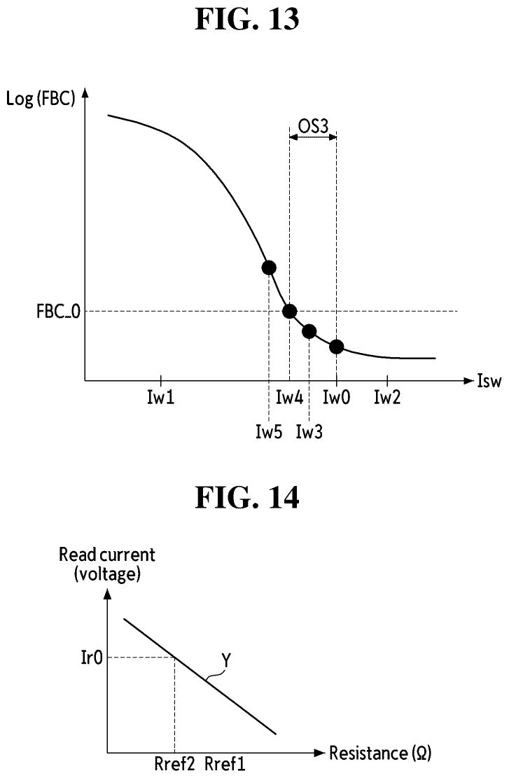

Referring to FIGS. 10 and 13, it is possible to test whether the fail bit count value Log(FBC) does not exceed the fail bit reference value FBC_0 when the first program current Iw0 is applied to an MRAM cell having the second reference resistor value Rref2 as the optimal reference resistor value.

At the time of the test operation on a plurality of MRAM cells which are included in the memory device and have the second reference resistor value Rref2 as the optimal reference resistor value, the plurality of MRAM cells are programmed with the first program current Iw0, and the test is performed whether the fail bit count value Log(FBC) due to the program operation exceeds the fail bit reference value FBC_0. In addition, it is possible to discriminate a program current in which the program current may be minimized within a range that does not exceed the fail bit reference value FBC_0.

If the fail bit count value Log(FBC) according to the program operation based on the first program current Iw0 does not exceed the fail bit reference value FBC_0, the MRAM cells may be programmed with a fourth program current Iw3 that is smaller than the first program current Iw0. For example, if the value of the program current is configured with 4 bits, when the value of the first program current Iw0 is logic “0100”, the value of the fourth program current Iw3 may be logic “0011.” Further, the test is performed whether the fail bit count value Log(FBC) according to the program operation based on the fourth program current Iw3 does not exceed the fail bit reference value FBC_0.

If the fail bit count value Log(FBC) according to the program operation based on the fourth program current Iw3 does not exceed the fail bit reference value FBC_0, the plurality of MRAM cells may be programmed with a fifth program current Iw4 that is smaller than the fourth program current Iw3. For example, if the value of the program current is configured with 4 bits, when the value of the fourth program current Iw3 is logic “0011”, the value of the fifth program current Iw4 may be logic “0010”. Further, the test is performed whether the fail bit count value Log(FBC) according to the program operation based on the fifth program current Iw4 does not exceed the fail bit reference value FBC_0.

If the fail bit count value Log(FBC) according to the program operation based on the fifth program current Iw4 does not exceed the fail bit reference value FBC_0, the plurality of MRAM cells may be programmed by a sixth program current Iw5 that is smaller than the fifth program current Iw4. For example, if the value of program current is configured with 4 bits, when the value of the fifth program current Iw4 is logic “0010”, the value of the sixth program current Iw5 may be logic “0001”. Further, the test is performed whether the fail bit count value Log(FBC) according to the program operation based on the sixth program current Iw5 does not exceed the fail bit reference value FBC_0.

If the fail bit count value Log(FBC) according to the program operation based on the sixth program current Iw5 exceeds the fail bit reference value FBC_0, the fifth program current Iw4 may be the optimal program current for the plurality of MRAM cells.

For example, for an MRAM cell having the second reference resistor value Rref2 as the optimal reference resistor value, the value of the fifth program current Iw4, which is the optimal program current finely trimmed by the fail bit reference value FBC_0, may be a value obtained by adding a third offset value OS3 to the value of the first program current Iw0, which is the optimal program current coarsely trimmed by the second reference resistor value Rref2.

FIG. 14 is a diagram for illustrating a relationship between the optimal reference resistor value determined on the basis of the size of the memory cell at the time of the test operation on the memory device and the value of optimal read current corresponding thereto.

Referring to FIG. 14, in some example embodiments, the value of the reference resistor of the memory device and the value of optimal read current (or read voltage) corresponding thereto may be coarsely inversely proportional. However, the reference resistor value of the memory device and the value of optimal program current corresponding thereto may not be exactly inversely proportional to each other.

Furthermore, in some example embodiments, when the sizes of the plurality of MRAM cells are equal to each other, the optimal reference resistor values may be equal to each other. When considering only the optimal reference resistor value, the value of the reference resistor of the MRAM cells included in the memory device and the value of optimal read current corresponding thereto may correspond to each other along the line Y. For example, the value of the optimal read current for the plurality of MRAM cells having the second reference resistor value Rref2 may be the first read current Ir0. Such a process is called coarse trim of the read current.

However, as discussed in FIG. 10, the optimal read current for the plurality of MRAM cells having the same cell size in the actual test may also be distributed within a specific range, in the manner similar to the value of the program current. This is because the value of the read current may be affected not only by the size of the MRAM cell but also by the perpendicular magnetic anisotropy (PMA) of each cell. Therefore, it may be beneficial to more finely trim the first read current Ir0 based on the reference resistor value. A detailed explanation of the method of fine trim will be provided below.

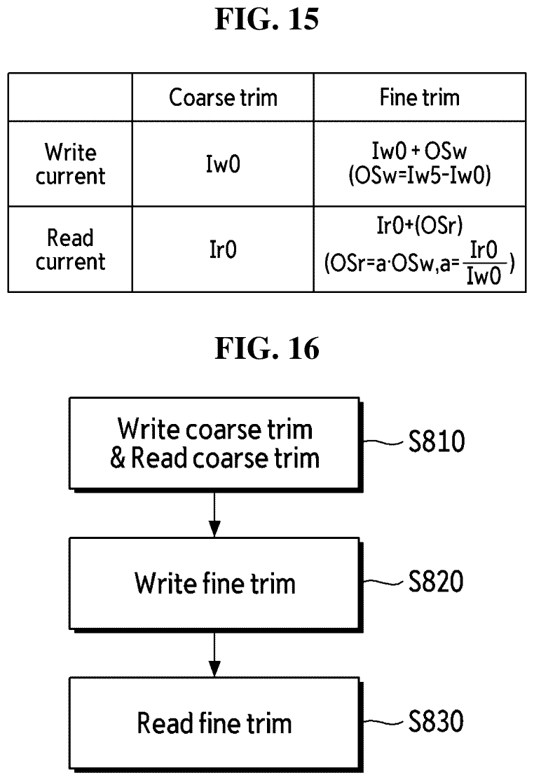

FIG. 15 is a table for illustrating the value of optimal program current and the value of optimal read current on the basis of the test operation on the memory device.

Referring to FIG. 15, the value of optimal program current corresponding to the optimal reference resistor value may be determined through the coarse trim and fine trim of the program current.

For example, as shown in FIG. 10, when only the size of the MRAM cell is taken into consideration, the value of the optimal program current for the MRAM cell in which an optimal reference resistor value is the second reference resistor value Rref2 may be the first program current Iw0. Such a process is called coarse trim of the program current.

As discussed in FIGS. 11 to 13, the value of the optimal program current for the MRAM cell which has the second reference resistor value Rref2 as the optimal reference resistor value on the basis of the coarsely trimmed first program current Iw0 and the fail bit reference value FBC_0 may be the sixth program current Iw5 or the fifth program current Iw4. This process is called fine trim of the program current.

A program offset OSw value may be calculated in the fine trim process of the program current. For example, referring to FIGS. 10 and 11, the program offset OSw value may be a value obtained by subtracting the value of the first program current Iw0 from the value of the sixth program current Iw5.

Similarly, in some example embodiments, when only the size of the MRAM cell is taken into consideration, the value of optimal read current for an MRAM cell in which the optimal reference resistor value is the second reference resistor value Rref2 may be the first read current Ir0. Such a process is called coarse trim of the read current.

The fine trim value for the first read current Ir0 may be obtained by adding the read offset OSr value to the first read current Ir0. Specifically, the read offset OSr may be a value for increasing the first read current Ir0 by a ratio of the program offset OSw to the first program current Iw0. That is, the ratio of the program offset OSw to the first program current Iw0 may be equal to or substantially equal to the ratio of the read offset OSr to the first read current Ir0. The read offset OSr may be determined through the following Equation 1 as seen in the fine trim of the read current shown in FIG. 15. Such a process is referred to as a fine trim of the read current.

$$OSr = a * OSw \qquad [ Equation 1 ]$$

As discussed above, in Equation 1, OSr may be the read offset OSr, OSw may be the program offset OSw, and a may be a ratio of the first read current Ir0 to the first program current Iw0.

The value of optimal reference resistor of the memory device and the values of the finely trimmed program current and read current corresponding thereto may be stored in the memory device. For example, the optimal reference resistor value, the value of program current corresponding thereto, and/or the value of read current may be stored in, but not limited to, an anti-fuse array of the memory device.

Furthermore, the values of optimal program current and read current stored in the memory device may be used at the time of general program operation at a user step. In addition, after product shipment, since the optimal program value or read value is selected depending on the position at which the memory device is formed on the substrate 1 at the time of program or read operation on the memory device, the reliability and/or durability of the memory device may be improved may be improved.

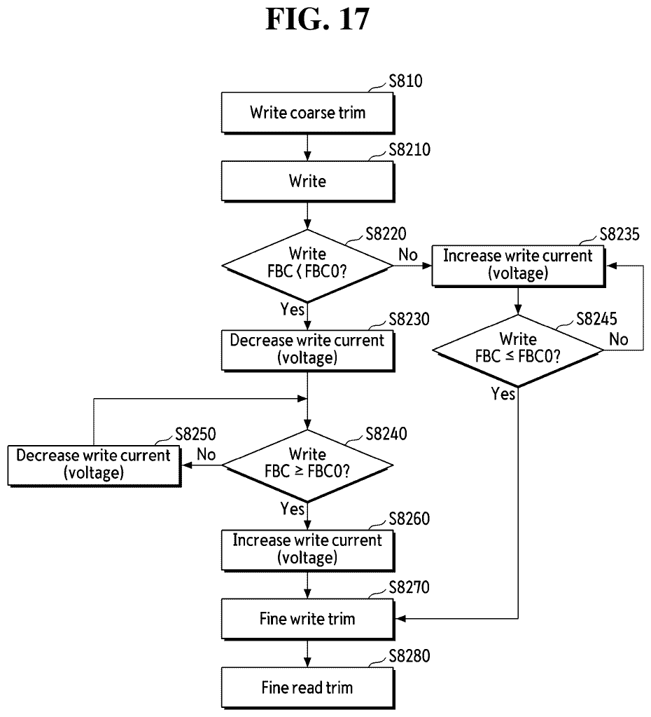

FIGS. 16 and 17 are flowcharts for illustrating a method for testing a memory device according to some example embodiments of the present disclosure. For reference, FIG. 17 corresponds to a flowchart for specifically explaining step S820 of FIG. 16.

Referring to FIG. 16, in order to perform a test on the memory device, a coarse trim of the program current (or voltage) and a coarse trim of the read current (or voltage) are performed (S810). The coarse trim of the program current and the coarse trim of the read current have been described above in FIGS. 10 and 14, and therefore the description will not be provided below.

Next, the fine trim on the program current is performed (S820). The fine trim on the program current has been described in FIGS. 11 to 13, and therefore the description thereof will not be provided.

Next, the fine trim on the read current is performed (S830). The fine trim on the read current may be performed in a manner of adding a read offset OSr value to the first read current Ir0. Specifically, referring to FIG. 15, the read offset OSr may be a value for increasing the first read current Ir0 by a ratio of the program offset OSw to the first program current Iw0.

Referring to FIG. 17, the coarse trim of the program current (or voltage) is performed to perform a test on the memory device (S810).

Referring to FIGS. 11 and 17, the program operation may be performed by applying a first program current Iw0 to an MRAM cell having the second reference resistor Rref2 as the optimal reference resistor value (S8210).

Further, it is possible to test whether the fail bit count value Log(FBC) exceeds the fail bit reference value FBC_0 (S8220).

If the fail bit count value Log(FBC) according to the program operation based on the first program current Iw0 exceeds the fail bit reference value FBC_0 (No), the plurality of MRAM cells may be programmed with a fourth program current Iw3 that is greater than the first program current Iw0 (S8235).

Next, the test is performed whether the fail bit count value Log(FBC) according to the program operation based on the fourth program current Iw3 does not exceed the fail bit reference value FBC_0 (S8245).

If the fail bit count value Log(FBC) according to the program operation based on the fourth program current Iw3 exceeds the fail bit reference value FBC_0 (No), the plurality of MRAM cells may be repeatedly programmed with a fifth program current Iw4 that is greater than the fourth program current Iw3 (S8235).

Further, the test is performed whether the fail bit count value Log(FBC) according to the program operation based on the fifth program current Iw4 does not exceed the fail bit reference value FBC_0 (S8245).

If the fail bit count value Log(FBC) according to the program operation based on the fifth program current Iw4 exceeds the fail bit reference value FBC_0 (No), the plurality of MRAM cells may be programmed with a sixth program current Iw5 that is greater than the fifth program current Iw4 (S8235).

Further, the test is performed whether the fail bit count value Log(FBC) according to the program operation based on the sixth program current Iw5 does not exceed the fail bit reference value FBC_0 (S8245).

If the fail bit count value Log(FBC) according to the program operation based on the sixth program current Iw5 does not exceed the fail bit reference value FBC_0 (Yes), the sixth program current Iw5 may be the optimal program current for the plurality of MRAM cells (S8270). This process is called fine trim of the program current. In the fine trimming process of the program current, the program offset OSw may be calculated.

Further, referring to FIGS. 15 and 17, a finely trimmed optimal read current may be discriminated on the basis of the coarsely trimmed read current and the program offset OSw (S8280).

Referring to FIGS. 13 and 17, a program operation may be performed by applying the first program current Iw0 to the MRAM cell having the second reference resistor value Rref2 as the optimal reference resistor value (S8210).

Further, the test is performed whether the fail bit count value Log(FBC) does not exceed a fail bit reference value FBC_0 (S8220).

If the fail bit count value Log(FBC) according to the program operation based on the first program current Iw0 does not exceed the fail bit reference value FBC_0 (Yes), the plurality of MRAM cells may be programmed with a fourth program current Iw3 that is smaller than the first program current Iw0 (S8230).

Further, the test is performed whether the fail bit count value Log(FBC) according to the program operation based on the fourth program current Iw3 does not exceed the fail bit reference value FBC_0 (S8240).

If the fail bit count value Log(FBC) according to the program operation based on the fourth program current Iw3 does not exceed the fail bit reference value FBC_0 (No), the plurality of MRAM cells may be programmed with a fifth program current Iw4 that is smaller than the fourth program current Iw3 (S8250).

Further, the test is performed whether the fail bit count value Log(FBC) according to the program operation based on the fifth program current Iw4 does not exceed the fail bit reference value FBC_0 (S8240).

If the fail bit count value Log(FBC) according to the program operation based on the fifth program current Iw4 does not exceed the fail bit reference value FBC_0 (S8250), the plurality of MRAM cells may be programmed with a sixth program current Iw5 that is smaller than the fifth program current Iw4.

Further, the test is performed whether the fail bit count value Log(FBC) according to the program operation based on the sixth program current Iw5 does not exceed the fail bit reference value FBC_0 (S8240).

If the fail bit count value Log(FBC) according to the program operation based on the sixth program current Iw5 exceeds the fail bit reference value FBC_0 (Yes), the fifth program current Iw4 may be the optimal program current for the plurality of MRAM cells (S8270). This process is called fine trim of the program current. In the fine trim process of the program current, the program offset OSw may be calculated.

Further, referring to FIGS. 15 and 17, a finely trimmed optimal read current may be discriminated on the basis of the coarsely trimmed read current and the program offset OSw (S8280).

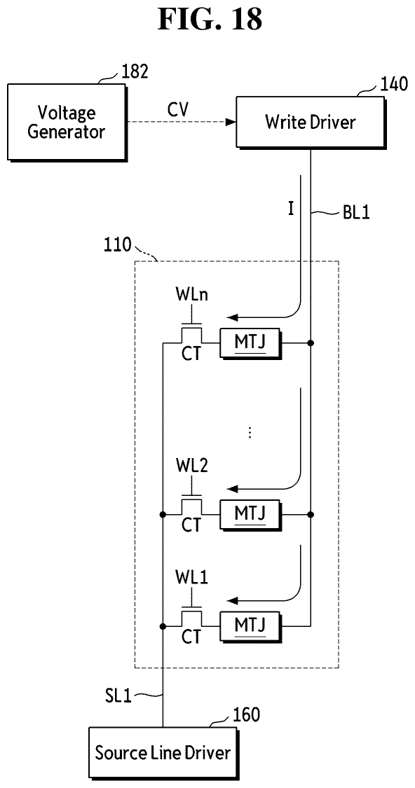

FIGS. 18 to 20 are diagrams for illustrating a test operation on the memory device according to some example embodiments.

Specifically, FIG. 18 may be related to pre-program on the memory device performed in the test step on the semiconductor device. Referring to FIG. 18, the memory cell array 110 may include a plurality of memory cells each including an MTJ element and a cell transistor. A write driver 140, a source line driver 160, and a voltage generator 182 are shown along with the memory cell array 110. For example, the voltage generator 182 may be the configuration of the control logic circuit and the voltage generator 180 of FIG. 2. For ease of explanation and simplicity of illustration, only n memory cells connected to the first bit line BL1 and the first source line SL1 are shown.

First, the voltage generator 182 may be configured to generate a value of voltage for performing pre-program on the memory cell array 110. Here, the voltage for performing the pre-program may mean a voltage of a level that is sufficient to prevent program fail from occurring on the memory cells. For example, the value of voltage for performing the pre-program may be, but are not limited to, a value greater than the value of the program voltage generally performed in the user step. For example, the value of voltage for performing the pre-program may be implemented as a code value CV for switching each element (e.g., each transistor) constituting the write driver 140.

The write driver 140 may perform a pre-program operation on the memory cell on the basis of the code value CV. The pre-program operation may include programming of the memory cells to have a parallel state and programming of the memory cells to have an anti-parallel state. For example, the write driver 140 may output a write current I (or a write voltage) corresponding to the code value CV. For example, the write driver 140 may include a driver circuit configured to generate a write current I to perform a pre-program operation on the memory cell.

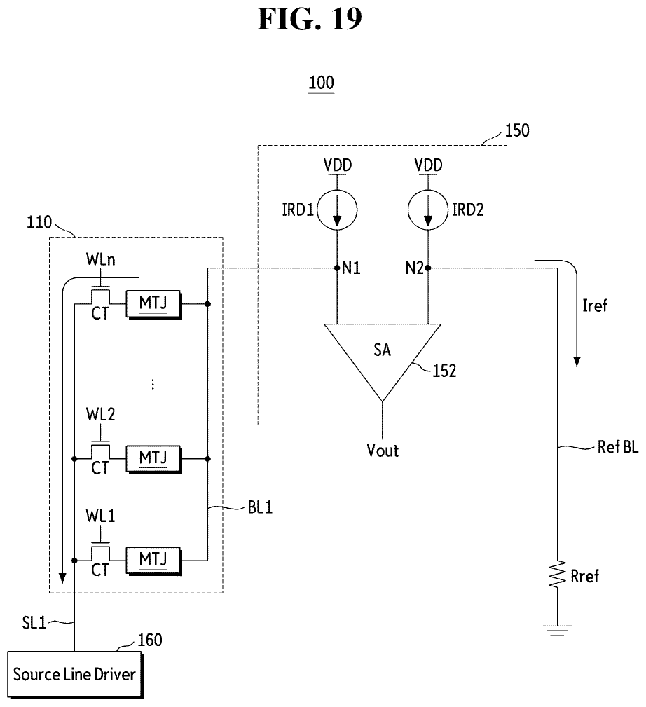

Specifically, some example embodiments of FIG. 19 may be related to discrimination of an optimal reference resistor value to be performed in the test step of the semiconductor device. That is, the test operation described through FIG. 19 may be performed after the test operation described through FIG. 18, and for ease of explanation, the memory cells of FIG. 19 are assumed to be programmed to the parallel state.

The memory cell array 110 may include a plurality of memory cells connected to a plurality of bit lines and a plurality of source lines. Each memory cell may include an MTJ element and a cell transistor. However, for simplicity of illustration, only memory cells connected to a first bit line BL1 and a first source line SL1 are shown. The first bit line BL1 may be connected to a first node N1, and the first source line SL1 may be connected to a source line driver 160.

The reference resistor Rref may be related to a voltage used to read data stored in the memory cell of the memory cell array 110. For example, the reference resistor Rref may be implemented with gate polysilicon used to generate a gate electrode of a transistor (e.g., a cell transistor CT) in the process of manufacturing the memory device 100. In this case, the value of the reference resistor Rref may be more easily variable by trimming the length, thickness, width, or the like of the implemented gate polysilicon, and as a result, the fail bits according to the variable value of the reference resistor Rref may be counted as described through FIG. 9.

The sensing circuit 150 may be configured to read the data stored in the memory cell connected to the first bit line BL1. For example, the sensing circuit 150 may include current sources that generate a first read current IRD1 and a second read current IRD2, and a sense amplifier 152.

The first read current IRD1 may be used to sense a voltage drop in a selected memory cell of the first bit line BL1. For example, the first read current IRD1 may be input to an MTJ connected to the selected word line (e.g., it is assumed to be WL2) connected to the first bit line BL1. As a result, a voltage drop occurs in the MTJ element connected to the second word line WL2.

The second read current IRD2 may be used to discriminate a voltage drop in the reference resistor Rref connected to the second node N2 through the reference bit line Ref BL. For example, a voltage drop may occur in the reference resistor Rref as the second read current IRD2 flows through the reference resistor Rref. As an example, FIG. 19 shows a reference current Iref to indicate the current passing through the reference resistor Rref, which may be considered to be the same or substantially/generally the same current as the second read current IRD2.

The sense amplifier 152 may sense a voltage difference between the first node N1 and the second node N2 and amplify the difference. For example, the voltage level of the first node N1 may be different from the voltage level of the second node N2. The amplified voltage difference may be output as an output voltage Vout, and may be used to discriminate data that is read from the memory cell.

In some example embodiments, in the test step of the memory device 100, the number of fail bits of the memory cells in the memory cell array 110 may be counted depending on the value of each variable reference resistor Rref. For example, when the memory cells of the memory cell array 110 are programmed to have a parallel state, the number of fail bits according to the value of the reference resistor Rref has a trend such as a graph G1 of FIG. 9, and when the memory cells are programmed to have an anti-parallel state, the number of fail bits according to the value of the reference resistor Rref has a trend such as a graph G3 of FIG. 9. The test device may derive a graph G3 on the basis of graphs G1 and G2, and may discriminate the value of optimal reference resistor corresponding to the smallest number of fail bits, and the values of optimal program current and read current corresponding thereto.

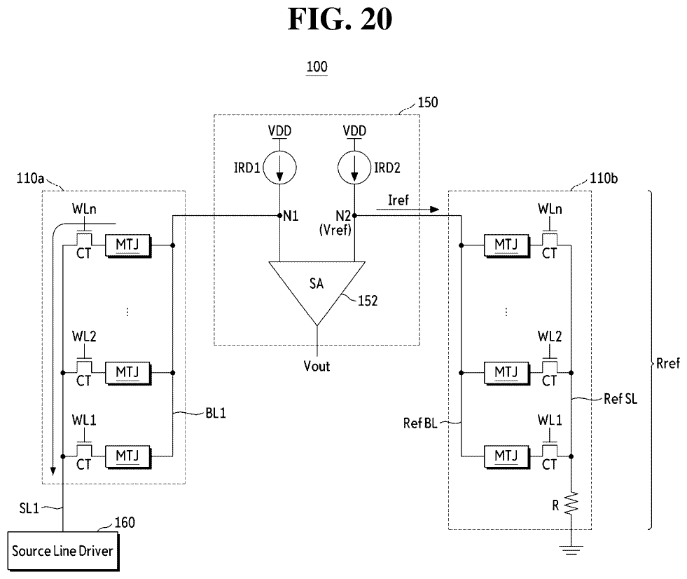

FIG. 20 conceptually shows performing of a test operation on the memory device according to some example embodiments of the present disclosure. Specifically, some example embodiments of FIG. 20 may be related to discrimination of an optimal reference resistor value to be performed in the test step on the semiconductor device. Further, some example embodiments of FIG. 20 may be the same or similar to some example embodiments of FIG. 19.

The memory cell array may include a first region 110a and a second region 110b. The memory cell array may include a plurality of memory cells each including an MTJ element and a cell transistor.

The first region 110a is a region in which data is stored, and may include a plurality of memory cells connected to a plurality of bit lines and a plurality of source lines. However, for simplicity of illustration, only the memory cells connected to the first bit line BL1 and the first source line SL1 are shown among the memory cells of the first region 110a.

The second region 110b may include configurations used to generate a reference voltage Vref used to read data stored in the memory cells of the first region 110a. For example, the second region 110b may include a plurality of memory cells and resistors R connected to the reference bit line Ref BL and the reference source line Ref SL. The memory cells of the second region 110b may be referred to as dummy memory cells in that they do not store data but are implemented to have the reference resistor Rref.

In some example embodiments, the memory cells of the first region 110a may be equal to or substantially equal to the memory cells of the second region 110b. The structure of the reference bit line Ref BL may be equal to substantially equal to the structure of the first bit line BL1, and the structure of the reference source line Ref SL may be equal to or substantially equal to the structure of the first source line SL1. That is, the first region 110a and the second region 110b may be provided by the same manufacturing process. However, in some example embodiments, the resistor R may or may not be provided.

The sensing circuit 150 may be configured to read data stored in the memory cells connected to the first bit line BL1. The sensing circuit 150 may include current sources that generate a first read current IRD1 and a second read current IRD2, and a sense amplifier 152. The sensing circuit 150 may discriminate a voltage drop in a selected memory cell of the first bit line BL1, using the first read current IRD1.

Furthermore, the sensing circuit 150 may discriminate a voltage drop in the memory cell connected to the reference bit line Ref BL, using the second read current IRD2. For example, the second read current IRD2 may be input to the memory cell selected by turning on the cell transistor CT through the reference bit line Ref BL. Therefore, the voltage drop in the second region 110b may be considered as a voltage drop due to the reference resistor Rref.

According to some example embodiments, it is not necessary to perform the fail bit counting on the first region 110a for each reference resistor, while replacing the reference resistor Rref as in some example embodiments of FIG. 19. Instead, the fail bits on the memory cells of the first region 110a may be counted, while varying the value of the reference resistor Rref by appropriately turning on or off each cell transistor CT constituting the second region 110b.

Furthermore, although only one reference bit line Ref BL is shown to be connected to the second node N2 in the drawing, more reference bit lines may be connected to the second node N2. For example, a reference bit line to which the memory cells having the same structure as the second region 110b shown in FIG. 20 are connected may be additionally connected to the second node N2.

The value of the optimal reference resistor discriminated in some example embodiments described through FIGS. 19 and 20 may be used to discriminate the values of the optimal program current and read current. For example, the values of the optimal program current and read current discriminated on the basis of the value of optimal reference resistor and the fail bit reference value may be stored in a specific region (e.g., an anti-fuse array, etc.) of the memory device 100.

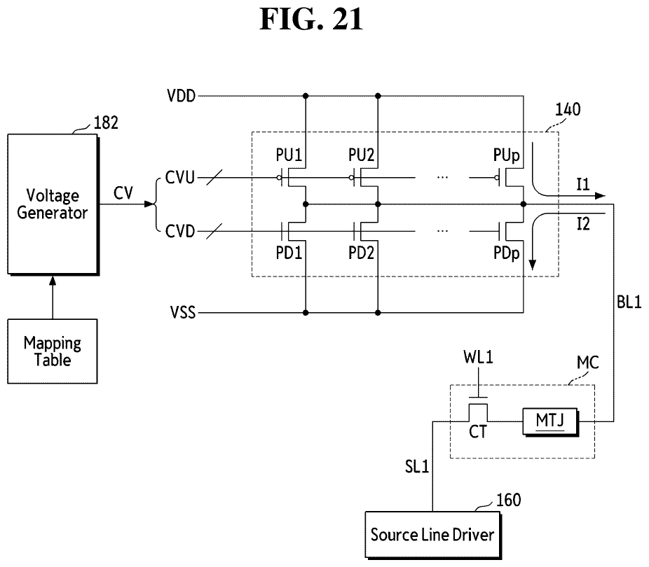

FIG. 21 is a diagram showing some example embodiments of the driver of FIG. 18. In particular, some example embodiments of FIG. 21 may be related to performing of a program operation according to the value of optimal write current discriminated at the test step on the semiconductor device.

The driver 140 may include transistors PU1 to Pup and PD1 to PDp. The transistors PU1 to Pup may be connected between the first bit line BL1 and a first power supply voltage VDD. The transistors PD1 to PDp may be connected between the first bit line BL1 and a second power supply voltage VSS. For example, the level of the first power supply voltage VDD may be higher than the level of the second power supply voltage VSS, and the level of the voltage of the first source line SL1 may be between the level of the first power supply voltage VDD and the level of the second power supply voltage VSS. For example, the power supply voltages VDD and VSS may be provided from the voltage generator 182 or may be provided from a separate voltage generator.

The driver 140 may be connected to the memory cells MC through a first bit line BL1 selected by a column decoder (130 in FIG. 2). In some example embodiments, additional drivers configured to be identical or substantially identical to the driver 140 may be provided for each of the memory cells connected to bit lines different from the first bit line BL1. However, for ease of illustration, the description of the additional driver circuits will not be provided.

The voltage generator 182 may generate a code value CV for controlling the driver 140. The code value CV may be based on a mapping table for a value of a predetermined program current. The code value CV may include a first code value CVU and a second code value CVD. The first code value CVU and the second code value CVD may be configured as a single code value CV or may be provided separately. However, as an example, the first code value CVU and the second code value CVD shown in FIG. 21 are shown as being provided as separate code values.

Each of the transistors PU1 to Pup may be turned on or off on the basis of the first code value CVU. For example, if each of the transistors PU1 to Pup is a P-type MOSFET (P-channel metal oxide semiconductor field effect transistor), each of the transistors PU1 to Pup may be turned on in response to a logic “0” bit, and turned off in response to a logic “1” bit.

Each of the transistors PD1 to PDp may be turned on or off on the basis of the code value CVD. For example, if each of the transistors PD1 to PDp is an N-type MOSFET (N-channel MOSFET), each of the transistors PD1 to PDp may be turned on in response to a bit of logic “1”, and turned off in response to a bit of logic “0”. However, the configuration of the driver 140 of FIG. 21 is from some example embodiments, and may be changed or modified differently from that shown in FIG. 21.

The turned-on transistors may provide paths for the write currents I1 and I2. Thus, the transistors PU1 to Pup and the transistors PD1 to PDp may drive the write currents I1 and I2 on the basis of the first code value CVU and the second code value CVD.

For example, when one or more of the transistors PU1 to Pup are turned on and the transistors PD1 to PDp are turned off, the voltage of the first bit line BL1 may be pulled up to the first power supply voltage VDD. In this case, a current I1 may be provided from the first bit line BL1 to the first source line SL1.

On the other hand, when the transistors PU1 to Pup are turned off and one or more of the transistors PD1 to PDp are turned on, the voltage of the first bit line BL1 may be pulled down to the second power supply voltage VSS. In this case, a current I2 may be provided from the first source line SL1 to the second bit line BL1. The data state of the memory cell MC may depend upon the write current I1 or I2.

The number of transistors that are turned on among the transistors PU1 to Pup may vary on the basis of the bits of the first code value CVU. The number of transistors that are turned on among the transistors PD1 to PDp may vary on the basis of the bits of the second code value CVD. The intensities of the write currents I1 and I2 may vary depending on the number of transistors that are turned on.

As the number of transistors that are turned on increases, the intensities of the write currents I1 and I2 may increase. The intensities of the write currents I1 and I2 may correspond to the sum of the intensities of the currents driven by the turned-on transistors. Thus, the intensities of the write currents I1 and I2 may be trimmed on the basis of the first code value CVU and the second code value CVD.

In this manner, the write driver 140 may be configured to drive write currents having different values. The values of the write currents I1 and I2 flowing through the memory cells MC may be trimmed to have one of the different values provided by the write driver 140.

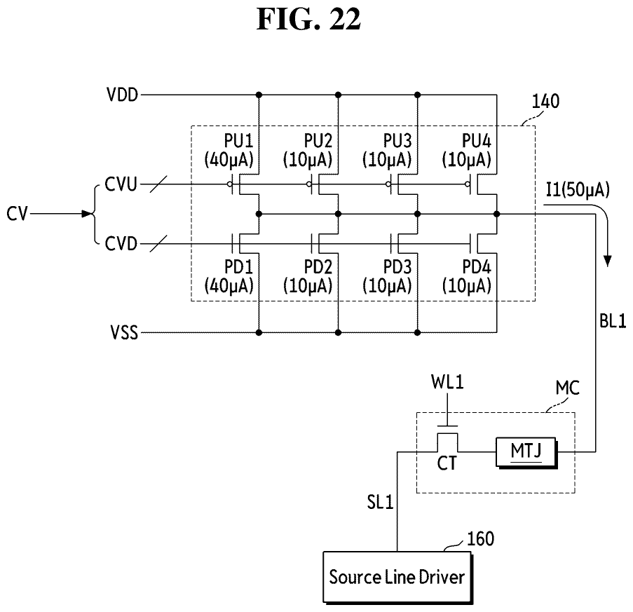

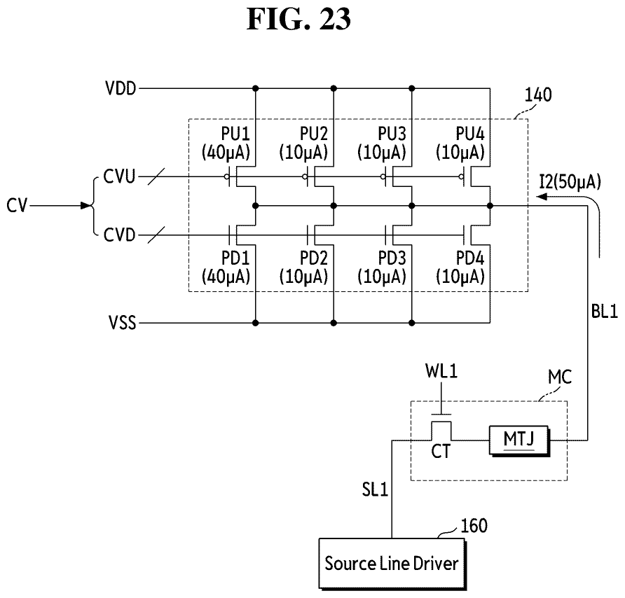

FIGS. 22 and 23 are diagrams for illustrating some example embodiments of a driver that operates on the basis of the code value which is output from the voltage generator of FIG. 21.

Referring to FIGS. 22 and 23, the driver 140 may include transistors PU1 to PU4 and transistors PD1 to PD4. As an example, each of the transistors PU1 and PD1 may have a channel width for driving a current of about or exactly 40 μA, and each of the transistors PU2 to PU4 and PD2 to PD4 may have a channel width for driving a current of about or exactly 10 μA.

In some example embodiments, FIG. 22 may be related to a case where the driver 140 attempts to pull up the voltage of the first bit line BL1 to the first power supply voltage VDD. In some example embodiments of FIG. 22, the driver 140 may receive input of voltages corresponding to a first code value CVU of logic “0011” and a second code value CVD of logic “0000” from the voltage generator (182 in FIG. 21).

Referring to FIG. 22, the transistors PD1 to PD4 may be turned off in response to the second code value CVD. The transistors PU1 and PU2 may be turned on in response to the bits “00” of the first code value CVU, and the transistors PU3 and PU4 may be turned off in response to the bits “11” of the first code value CVU. Thus, a write current I1 of about or exactly 50 μA may be driven through the turned-on transistors PU1 and PU2.

In some example embodiments, FIG. 23 may be related to a case where the driver 140 attempts to pull down the voltage of the first bit line BL1 to the second power supply voltage VSS. In some example embodiments of FIG. 23, the driver 140 may receive the first code value CVU of logic “1111” and the second code value CVD of logic “1100” from the voltage generator 182.

Referring to FIG. 23, the transistors PU1 to PU4 may be turned off in response to the first code value CVU. The transistors PD1 and PD2 may be turned on in response to the bits “11” of the second code value CVD, and the transistors PD3 and PD4 may be turned off in response to the bits “00” of the second code value CVD. Thus, a write current I2 of about or exactly 50 μA may be driven through the turned-on transistors PD1 and PD2.

In some example embodiments, FIG. 22 may be related to a case where data of logic “0” is to be stored in the memory cell MC, and FIG. 23 may be related to a case where data of logic “1” is to be stored in the memory cell MC. For example, the voltage generator 182 may include a configuration such as a switch and a multiplexer to provide the code value to the transistors PU1 to PU4 and PU1 to PU4 constituting the driver.

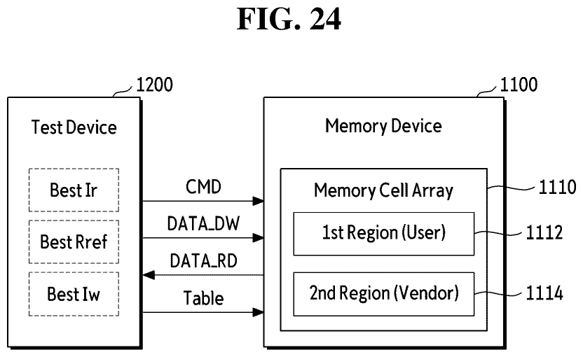

FIG. 24 is a diagram for illustrating a test system according to some example embodiments of the present disclosure.

The test system includes a memory device 1100 and a test device 1200.

The memory device 1100 includes a memory cell array. In some example embodiments, the memory device 1100 may be some example embodiments of the memory devices C1 and C2 described through FIGS. 1 to 23. The memory cell array 1110 may include a first region 1112 and a second region 1114. For example, the first region 1112 may be a user region in which data intended by a user is stored. The second region 1114 may be a vendor region in which data intended by a memory vendor is stored. For example, the second region 1114 may store the value of optimal reference resistor and the values of optimal write current (or voltage) and read current (or voltage) corresponding thereto described through FIGS. 1 to 23.

The test device 1200 may perform various test operations on the memory device 1100. To this end, the test device 1200 may send a command CMD to the memory device 1100.

In some example embodiments, the command CMD may include a command for programming the first region 1112 of the memory cell array to a particular program state (a parallel state or an anti-parallel state). Along with sending of the command CMD, the test device 1200 may send dummy write data DATA_DW for programming the first region 1112 to the parallel state or the anti-parallel state.

In some example embodiments, the command CMD may perform a read operation for counting the number of fail bits for each reference resistor for the particular program state (e.g., the parallel state or the anti-parallel state). The read data DATA_RD may be received from the memory device as a read result.

In some example embodiments, the test device 1200 may count the number of fail bits for each reference resistor on the basis of the read data DATA_RD received from the memory device 1100, and may discriminate the value of the optimal reference resistor Rref on the basis of the counting result, and may discriminate the value of optimal read voltage (or current) on the basis of the value of the optimal reference resistor Rref and the fail bit reference value FBC_0.

In some example embodiments, the value of the optimal reference resistor Rref, and the values of the optimal program current (or voltage), and the optimal read current (or voltage) discriminated by the test device 1200 may be stored in the memory device 1100 in the form of a table. For example, the table may be stored in the second region 1114 of the memory cell array 1110. For example, the second region 1114 may include an anti-fuse cell array.

Meanwhile, some example embodiments may be related to a case where in the unit of a memory device (e.g., a semiconductor chip), a pre-program operation is performed, a fail bit counting is performed, the value of the optimal reference resistor is discriminated, and the values of optimal program current and optimal read current are discriminated by the fail bit reference value FBC_0. However, in some example embodiments, the value of optimal read current may be discriminated depending on other criteria, not in the unit of the memory device (e.g., the semiconductor chip). For example, even in a single memory device, because the distances of the memory cells spaced apart from the center of the substrate are different from one another, the memory cells of each memory cell may be divided into a plurality of regions and the value of optimal read current may be discriminated for each region.

According to some example embodiments as disclosed above, the optimal reference resistor value of the memory device may be discriminated through only two pre-program operations (e.g., the parallel state and the anti-parallel state) for the memory device. Further, the values of optimal program current and read current can be discriminated on the basis of the value of optimal reference resistor and the fail bit reference value. Therefore, the test time and test cost for determining the value of optimal read current may decrease. In addition, because the read operation is performed using the value of optimal read current according to the characteristics of the cells of the memory device, the reliability of the memory device may be improved.

For example, according to some example embodiments, there may be an increase in reliability, operating parameters (e.g., data accuracy), speed (e.g., fewer error corrections, fewer incompatible results), accuracy, and/or power efficiency of the memory device based on the above methods. Therefore, the improved devices and methods overcome the deficiencies of the conventional devices and methods while reducing resource consumption, and/or improving reliability, durability, data accuracy, operating parameters, and resource allocation (e.g., latency).

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Any or all of the elements described with reference to the figures may communicate with any or all other elements described with reference to figures. For example, any element may engage in one-way and/or two-way and/or broadcast communication with any or all other elements in the figures, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

Although some example embodiments of the present inventions have been described above with reference to the accompanying drawings, the present inventions are not limited to the above embodiments, and may be fabricated in various different forms. Those skilled in the art will appreciate that the present inventions may be embodied in other specific forms without changing the technical spirit or essential features of the present inventions. Accordingly, the above-described example embodiments should be understood in all respects as illustrative and not restrictive.

What is claimed is:

1. A memory device comprising:
a memory cell array including
a first region, and
a second region configured to store
a value of a program current discriminated based on a value of a reference resistor for distinguishing between a parallel state and an anti-parallel state of a programmed memory cell,
a fail bit reference value indicating a percentage of error bits allowable in the memory cell array, and
a value of a read current discriminated based on the value of the reference resistor and the value of the program current; and
a sensing circuit configured to generate the read current and perform a read operation on the first region based on the read current,
the value of the program current including a value of a second program current generated by adding a first offset value discriminated based on the fail bit reference value to a value of a first program current discriminated based on the value of the reference resistor, and
the value of the read current including a value of a first read current discriminated based on the value of the reference resistor, and a value of a second read current generated by adding a second offset value generated based on the first offset to the value of the first read current.

2. The memory device of claim 1,
wherein a ratio of the first offset value to the value of the first program current is equal to a ratio of the second offset value to the value of the first read current.

3. The memory device of claim 1, wherein
a percentage of error bits generated based on the value of the first program current exceeds the fail bit reference value, and
a percentage of error bits generated based on the value of the second program current does not exceed the fail bit reference value.

4. The memory device of claim 1, wherein
a percentage of error bits generated based on the value of the first program current is smaller than the percentage of error bits generated based on the value of the second program current, and
a percentage of error bits generated based on the value of the second program current does not exceed the fail bit reference value.

5. The memory device of claim 1, further comprising:
a voltage generator configured to generate a code value corresponding to the value of the second program current; and
a write driver configured to drive the second program current for storing data in the first region based on the code value.

6. The memory device of claim 5, wherein the write driver includes:
first type transistors having one end connected to a first power supply voltage and another end connected to an output node, and
second type transistors having one end connected to a second power supply voltage and another end connected to the output node.

7. The memory device of claim 6, wherein
the code value includes a first code value and a second code value,
the first type transistors configured to receive a corresponding bit among bits of the first code value from the voltage generator, and
the second type transistors configured to receive a corresponding bit among bits of the second code value from the voltage generator.

8. The memory device of claim 1, wherein
the memory cell array includes a plurality of memory cells,
each of the plurality of memory cells includes a cell transistor having one end connected to a source line and a gate electrode connected to a word line, and
a magnetic tunneling junction element having one end connected to another end of the cell transistor and another end connected to a bit line.

9. The memory device of claim 1, wherein the sensing circuit includes:
a current source configured to generate a first read current and a third read current; and
a sense amplifier configured to amplify a difference between a voltage drop at a first node caused by applying the first read current to a first bit line connected to a selected memory cell and a voltage drop at a second node caused by applying the third read current to a reference bit line.

10. The memory device of claim 9,
wherein a second reference resistor having a same value as the value of the reference resistor is connected to the reference bit line.

11. The memory device of claim 10,
wherein the second reference resistor is implemented as gate polysilicon for forming a gate electrode of a transistor constituting the memory cell array.

12. The memory device of claim 9,
wherein at least one memory cell having a same structure as the selected memory cell is connected to the reference bit line.

13. The memory device of claim 1,
wherein the second region is implemented as an anti-fuse cell array.

14. An operating method of a memory device, comprising:
programming a memory device to a first state;
counting fail bits of the memory device programmed to the first state for each reference resistor, using a plurality of resistors having different values from each other;
programming the memory device to a second state;
counting fail bits of the memory device programmed to the second state for each reference resistor, using the plurality of resistors;
selecting a reference resistor among the plurality of resistors, based on the counting results associated with the first state and the counting results associated with the second state;
discriminating a value of a first program current for the memory device based on the value of the selected reference resistor;
discriminating a value of a second program current for the memory device, based on the value of the first program current and a fail bit reference value indicating a percentage of error bits allowable in the memory device;
discriminating a value of a first read current for the memory device based on the value of the selected reference resistor; and
discriminating a value of a second read current for the memory device, based on the value of the first read current and a first offset value obtained by subtracting the value of the first program current from the value of the second program current.

15. The operating method of the memory device of claim 14, wherein
the selecting of the reference resistor is performed based on a result obtained by summing up the counting results associated with the first state and the counting results associated with the second state for each resistor, and
the reference resistor causes a smallest number of fail bits among results summed up for each of the plurality of resistors.

16. The operating method of the memory device of claim 14, wherein
the discriminating of the value of the second read current includes adding a second offset value to the value of the first read current to discriminate the value of the second read current, and
a ratio of the first offset value to the value of the first program current is equal to a ratio of the second offset value to the value of the first read current.

17. The operating method of the memory device of claim 14,
wherein a percentage of error bits generated based on the value of the second program current does not exceed the fail bit reference value.

18. The operating method of the memory device of claim 17,
wherein a percentage of error bits generated based on the value of the first program current exceeds the fail bit reference value.

19. The operating method of the memory device of claim 17,
wherein the percentage of error bits generated based on the value of the first program current is smaller than the percentage of error bits generated based on the value of the second program current.

20. A memory device comprising:
a memory cell array including a first region, and a second region configured to store a value of a program current discriminated, based on a value of a reference resistor for distinguishing between a parallel state and an anti-parallel state of a programmed memory cell and a fail bit reference value indicating a percentage of error bits allowable in the memory cell array, and a value of a read current discriminated based on the value of the reference resistor and the value of the program current; and
a sensing circuit configured to generate the read current and perform a read operation on the first region based on the read current,
the value of the program current including a value of a second program current generated by adding a first offset value discriminated based on the fail bit reference value to a value of a first program current discriminated based on the value of the reference resistor, and
the value of the read current including a value of a first read current discriminated based on the value of the reference resistor, and a value of a second read current generated by adding a second offset value generated based on the first offset to the value of the first read current,
a percentage of error bits generated based on the value of the second program current does not exceed the fail bit reference value, and
a ratio of the first offset value to the value of the first program current is equal to a ratio of the second offset value to the value of the first read current.
